(19) United States
(12) Patent Application Publication
(10) Pub. No.: US 2019/0257988 A1
(43) Pub. Date: Aug. 22, 2019

(54) DISPLAY DEVICE

(71) Applicant: Au Optronics Corporation, Hsinchu (TW)

(72) Inventors: Yu-Jui Chiu, Hsinchu (TW); Yen-Huang Hsu, Hsinchu (TW)

(73) Assignee: Au Optronics Corporation, Hsinchu (TW)

(21) Appl. No.: 15/990,845

(22) Filed: May 29, 2018

(30) Foreign Application Priority Data
Feb. 22, 2018 (TW) 107105934

(51) Int. Cl. G02B 5/20; H01L 27/12

(52) U.S. Cl. CPC G02B 5/20; H01L 27/124

(57) ABSTRACT

A display device includes at least one peripheral pixel, at least one non-peripheral pixel and a black matrix. The at least one peripheral pixel includes a first color resist, a second color resist adjacent to the first color resist and a third color resist adjacent to the second color resist. The at least one non-peripheral pixel is adjacent to the at least one peripheral pixel. The at least one non-peripheral pixel includes a fourth color resist. The black matrix at least overlaps at least one of the first color resist, the second color resist and the third color resist.

### CROSS-REFERENCE TO RELATED APPLICATION

This application claims the priority benefit of Taiwan application serial no. 107105934, filed on Feb. 22, 2018. The entirety of the above-mentioned patent application is hereby incorporated by reference herein and made a part of this specification.

### BACKGROUND

### Field of the Disclosure

The disclosure is related to a display device, and particularly to a display device in which a black matrix overlaps a peripheral pixel.

### Description of Related Art

Along with advancement of technologies, the screen-to-body ratio and aesthetic value are important criteria for consumers to take into consideration when choosing display device. In order to increase the aesthetic value of display device, the corner of appearance of some display devices is designed to have an arc shape, that is, by replacing common right angle with round angle so as to make the appearance look gentler. However, to increase the screen-to-body ratio of the display device with the arc design, the corner of display panel also needs to match the arc design of the appearance of the display device.

However, the display panel that is designed with an arc-shaped corner has the problem of non-unifoini color at the edge, such as mura defect with non-uniform color or saw-tooth color non-uniformity, which significantly affect the quality of display device. Currently a solution that can solve all of the above-mentioned problems is urgently in need.

### SUMMARY OF THE DISCLOSURE

The disclosure provides a display device which may solve the problem of non-uniform color of display device.

In the disclosure, a display device includes at least one peripheral pixel, at least one non-peripheral pixel and a black matrix. The at least one peripheral pixel includes a first color resist, a second color resist adjacent to the first color resist and a third color resist adjacent to the second color resist. The at least one non-peripheral pixel is adjacent to the at least one peripheral pixel. The at least one non-peripheral pixel includes a four color resist. The black matrix at least overlaps at least one of the first color resist, the second color resist and the third color resist.

According to the above, in the display device of the disclosure, with the black matrix which at least overlaps at least one of the first color resist, the second color resist and the third color resist, the problem of non-uniform color of display device may be solved, thereby improving the display quality of display device.

In order to make the aforementioned features and advantages of the disclosure more comprehensible, embodiments accompanying figures are described in detail below.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a part of elements of a display device according to an embodiment of the disclosure.

FIG. 2 is a schematic top view of a part of elements of a display device according to an embodiment of the disclosure.

FIG. 3 is a schematic top view of a part of elements of a display device according to an embodiment of the disclosure.

FIG. 4 is a schematic top view of a part of elements of a display device according to another embodiment of the disclosure.

### DESCRIPTION OF EMBODIMENTS

The disclosure will be described more comprehensively hereinafter with reference to the accompanying drawings, in which embodiments of the disclosure are shown. As those skilled in the art may realize, the described embodiments may be modified in various different ways without departing from the spirit or scope of the disclosure.

Unless defined otherwise, all technical and scientific terms used herein have the same meaning as commonly understood by one of ordinary skill in the art to which exemplary embodiments belong. It is noted that the use of any and all examples, or exemplary terms provided herein, is intended merely to better illuminate exemplary embodiments and is not a limitation on the scope of the disclosure unless otherwise specified. Further, unless defined otherwise, all terms defined in generally used dictionaries may not be overly interpreted.

The exemplary embodiment is described below with reference of a cross-sectional view of a schematic diagram of an idealized embodiment. Therefore, a shape change of the figure serving as a result of manufacturing techniques and/or tolerances may be expected. Therefore, the embodiment of the disclosure should not be construed as limited to a particular shape of a region as shown herein, but includes a shape deviation caused by manufacturing tolerance. For example, a shown or described flat area may generally have rough and/or non-linear features. Moreover, a shown acute angle may be round. Therefore, a region shown in the figure is essentially schematic, and a shape thereof is not intended to show an accurate shape of the region, and is not intended to limit a range of the claims of the disclosure.

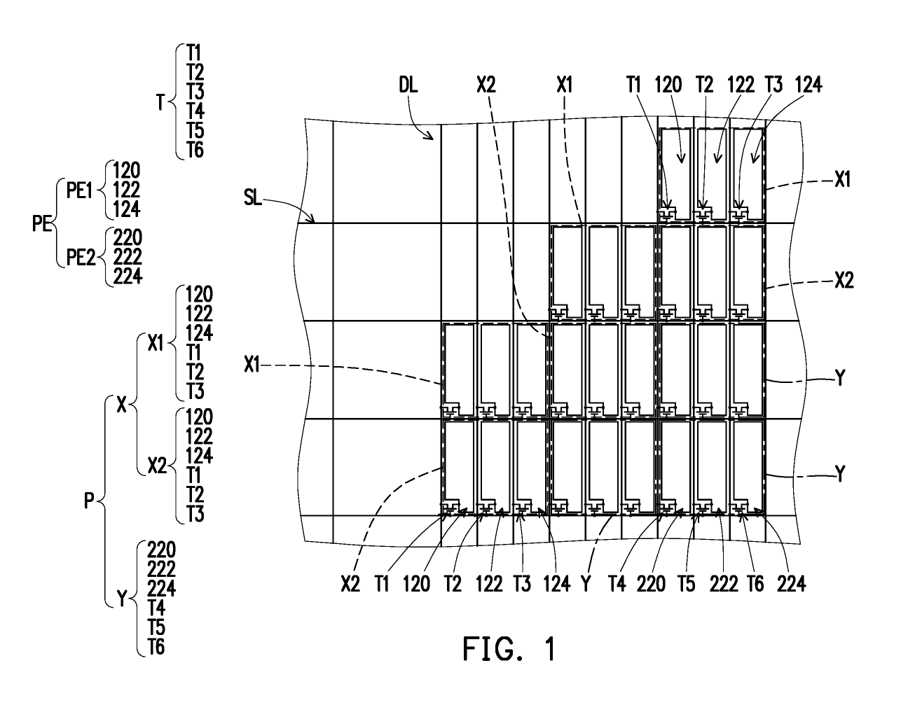

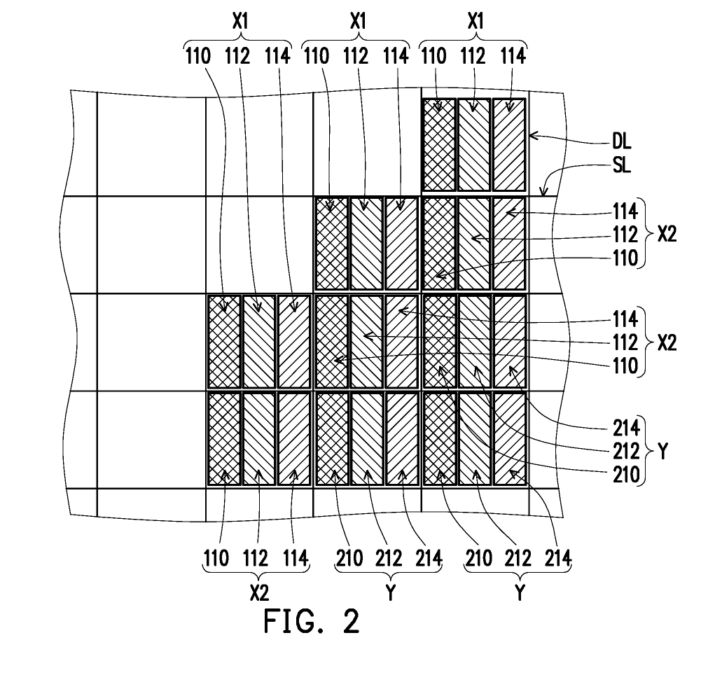

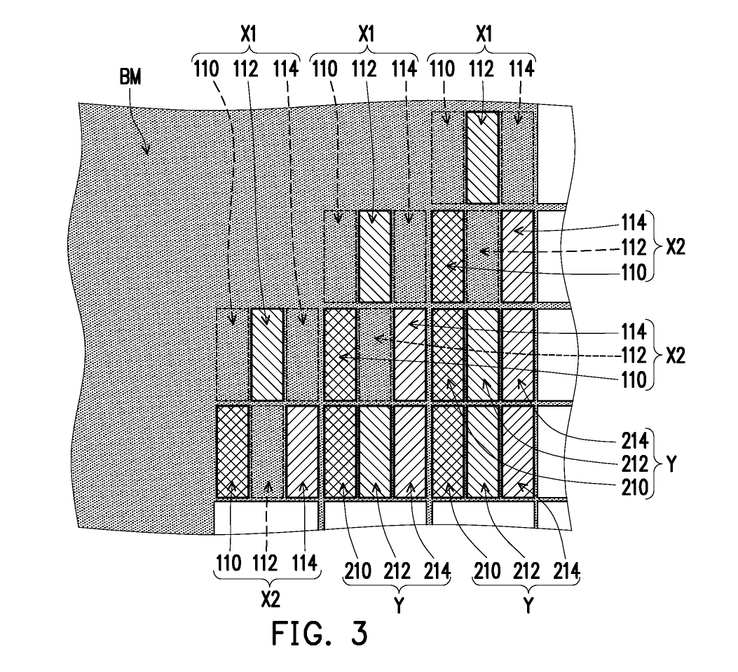

FIG. 1 is a schematic top view of a part of elements of a display device according to an embodiment of the disclosure. FIG. 2 is a schematic top view of a part of elements of a display device according to an embodiment of the disclosure. FIG. 3 is a schematic top view of a part of elements of a display device according to an embodiment of the disclosure. FIG. 1 through FIG. 3 are, for example, schematic top views of different elements at the same position of the display device.

Referring to FIG. 1, FIG. 1 illustrates a plurality of scan lines SL, a plurality of data lines DL and a plurality of pixel structures P in a display device, and other elements are omitted. The scan lines SL and the data lines DL are arranged in interlace, and each of the pixel structures P is electrically connected one of the corresponding scan lines SL and one of the corresponding data lines DL. The embodiment of the disclosure is exemplified with that the extending direction of the scan lines SL and the extending direction of the data lines DL are not parallel with each other. For example, the extending direction of the scan lines SL and the extending direction of the data lines DL are perpendicular to each other. Generally the scan lines SL and the data lines DL are formed of metal material, which should not be construed as a limitation to the disclosure. According to other embodiments, the scan lines SL and the data lines DL may be formed of other conductive material (e.g., nitride of metal material, oxide of metal material, oxynitride of metal material or other suitable material) or a stacked layer of metal material and other conductive material.

Further referring to FIG. 1, each of the pixel structures P includes a switch element T and a pixel electrode PE. For ease of illustration, the switch element T in FIG. 1 is only denoted by a symbol. The switch element T may be a bottom gate thin film transistor or a top gate thin film transistor, which includes a gate, a channel, a source and a drain. The gate of the switch element T is electrically connected to one of the scan lines SL, the source of the switch element T is electrically connected to one of the data lines DL, and the drain of the switch element T is electrically connected to the pixel electrode PE. In some embodiments, the switch element T and the pixel electrode PE are further electrically connected through other driving element (not shown), but the disclosure provides no limitation thereto. Although the embodiment is exemplified with that each of the pixel structures P includes three switch elements and three pixel electrodes, the disclosure provides no limitation thereto. Each of the pixel structures of the disclosure may include one or more switch elements and one or more pixel electrodes.

The pixel electrode PE may be a transmissive pixel electrode, a reflective pixel electrode or a half-transmissive and half-reflective pixel electrode. The material of the transmissive pixel electrode includes metal oxide such as indium-tin oxide, indium-zinc oxide, aluminum-tin oxide, aluminum-zinc oxide, indium-germanium-zinc oxide or other suitable oxide or a stacked layer of at least two of the above. The material of the reflective pixel electrode includes metal material having high reflectivity.

Further referring to FIG. 1, the switch element T is, for example, a first switch element T1, a second switch element T2, a third switch element T3, a fourth switch element T4, a fifth switch element T5 or a sixth switch element T6. The pixel electrode PE is, for example, a peripheral pixel electrode PE1 or a non-peripheral pixel PE2. The peripheral pixel electrode PE1 is, for example, a peripheral pixel electrode 120, a peripheral pixel electrode 122 or a peripheral pixel electrode 124. The non-peripheral pixel electrode PE2 is, for example, a non-peripheral pixel electrode 220, a non-peripheral pixel electrode 222 or a non-peripheral pixel electrode 224. The first switch element T1 is electrically connected to the peripheral pixel electrode 120, the second switch element T2 is electrically connected to the peripheral pixel electrode 122 and the third switch element T3 is electrically connected to the peripheral pixel electrode 124. The fourth switch element T4 is electrically connected to the non-peripheral pixel electrode 220, the fifth switch element T5 is electrically connected to the non-peripheral pixel electrode 222 and the sixth switch element T6 is electrically connected to the non-peripheral pixel electrode 224. In the embodiment, the pixel structure P is, for example, a peripheral pixel X or a non-peripheral pixel Y. The non-peripheral pixel Y is adjacent to the peripheral pixel X. The area of the peripheral pixel X and the area of the non-peripheral pixel Y are, for example, defined by two adjacent scan lines SL and two corresponding data lines DL. In some embodiments, the area of the peripheral pixel X and the area of the non-peripheral pixel Y are approximately the same. In the embodiment, the peripheral pixel X includes the first switch element T1, the second switch element T2, the third switch element T3 and the peripheral pixel electrodes 120, 122 and 124. The non-peripheral pixel Y includes the fourth switch element T4, the fifth switch element T5, the sixth switch element T6 and the non-peripheral pixel electrodes 220, 222 and 224. The peripheral pixel X is, for example, a first peripheral pixel X1 or a second peripheral pixel X2 adjacent to the first peripheral pixel X1. The second peripheral pixel X2 is disposed between the first peripheral pixel X1 and the non-peripheral pixel Y.

Referring to both of FIG. 1 and FIG. 2, FIG. 2 illustrates a plurality of scan lines SL, a plurality of data lines DL, a plurality of first color resists 110, a plurality of second color resists 112, a plurality of third color resists 114, a plurality of fourth color resists 210, a plurality of fifth color resists 212 and a plurality of sixth color resists 214 in the display device, and other elements are omitted. The single peripheral pixel X includes three sub-pixels, and each of the sub-pixels respectively includes the first color resist 110, the second color resist 112 adjacent to the first color resist 110 and the third color resist 114 adjacent to the second color resist 112. The first color resist 110, the second color resist 112 and the third color resist 114 of the single peripheral pixel X are different colors, and the first color resist 110, the second color resist 112 and the third color resist 114 are selected from red color resist, green color resist and blue color resist. That is to say, the three sub-pixels of the single peripheral pixel X respectively includes red color resist, green color resist and blue color resist. The areas of the first color resist 110, the second color resist 112 and the third color resist 114 of the peripheral pixel X are approximately the same. The peripheral pixel electrode 112 overlaps the first color resist 110, the peripheral pixel electrode 122 overlaps the second color resist 112 and the peripheral pixel electrode 124 overlaps the third color resist 114. Although the embodiment is exemplified with that each of the pixel structures P includes three switch elements and three pixel electrodes respectively overlapping the three color resists, that is, each of the color resists corresponds to one pixel electrode respectively, the disclosure provides no limitation thereto. In other embodiments, each of the peripheral pixels may include one switch element and one pixel electrode overlapping the three color resists.

In the embodiment, the single non-peripheral pixel Y includes three sub-pixels, each of the sub-pixels respectively includes the fourth color resist 210, the fifth color resist 212 adjacent to the fourth color resist 210 and the sixth color resist 214 adjacent to the fifth color resist 212. The fourth color resist 210, the fifth color resist 212 and the sixth color resist 214 of the single non-peripheral pixel Y are different colors, and the fourth color resist 210, the fifth color resist 212 and the sixth color resist 214 are selected from the red color resist, the green color resist and the blue color resist. In other words, the three sub-pixels of the single non-peripheral pixel Y respectively include the red color resist, the green color resist and the blue color resist. The areas of the fourth color resist 210, the fifth color resist 212 and the sixth color resist 214 of the non-peripheral pixel Y are approximately the same. In the embodiment, the fourth color resist 210, the fifth color resist 212 and the sixth color resist 214 in the non-peripheral pixel Y includes the red color resist, the green color resist and the blue color resist; in this manner, the light passing through the non-peripheral pixel Y may be blended into white light. The areas of fourth color resist 210, the fifth color resist 212 or the sixth color resist 214 of the single non-peripheral pixel Y are approximately equal to the area of the first color resist 110, the area of the second color resist 112 or the area of the third color resist 114 in the single peripheral pixel X. The non-peripheral pixel electrode 220 overlaps the fourth color resist 210, the non-peripheral pixel electrode 222 overlaps the fifth color resist 212 and the non-peripheral pixel electrode 224 overlaps the sixth color resist 214.

Referring to both of FIG. 1 and FIG. 3, FIG. 3 illustrates a black matrix BM, the plurality of first color resists 110, the plurality of second color resists 112, the plurality of third color resists 114, the plurality of fourth color resists 210, the plurality of fifth color resists 212 and the plurality of sixth color resists 214 in the display device, and other elements are omitted. The black matrix BM at least overlaps at least one of the first color resist 110, the second color resist 112 and the third color resist 114 in the single peripheral pixel X. The edge of the peripheral pixel X and the edge of the non-peripheral pixel Y both overlap the black matrix BM. The black matrix BM overlaps the scan lines SL and the data lines DL. The overlapping area of the first peripheral pixel X1 and the black matrix BM is M, and the overlapping area of the second peripheral pixel X2 and the black matrix BM is N, and M>N.

Referring to FIG. 1 and FIG. 3, in the embodiment, the first color resist 110 and the third color resist 114 of the first peripheral pixel X1 overlap the black matrix BM, and the second color resist 112 of the second peripheral pixel X2 overlaps the black matrix BM, for example, two comb-shaped black matrixes BM overlap the first color resist 110 and the third color resist 114 of the first peripheral pixel X1, and one comb-shaped black matrix BM overlaps the second color resist 112 of the second peripheral pixel X2. As the number of the comb-shaped black matrix BM is increased, the transmittance of the peripheral pixel X is decreased. In other words, the transmittance of the first peripheral pixel X1 is smaller than the transmittance of the second peripheral pixel X2, the transmittance may be adjusted to make the saw-tooth color non-uniformity become bluffed. In the embodiment, in the first peripheral pixel X1 and the second peripheral pixel X2 adjacent to each other, the first color resist 110 of the second peripheral pixel X2, the second color resist 112 of the first peripheral pixel X1 and the third color resist 114 of the second peripheral pixel X2 include the red color resist, the green color resist and the blue color resist. In this manner, the light passing through the first peripheral pixel X1 and the second peripheral pixel X2 adjacent to each other may be blended into white light such that occurrence of non-unifoimity of mura color may be avoided.

According to the above, in the display device of the disclosure, with the black matrix BM which at least overlaps at least one of the first color resist 110, the second color resist 112 and the third color resist 114, the problem of color non-uniformity in the display device may be solved, thereby improving the display quality of the display device.

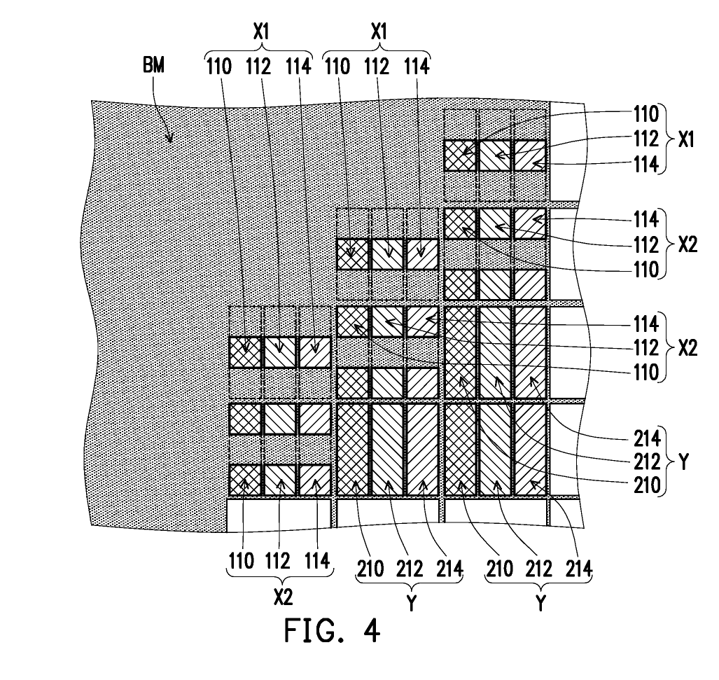

FIG. 4 is a schematic view of a display device according to another embodiment of the disclosure. It should be pointed out that the embodiment of FIG. 4 uses the reference numerals and some descriptions provided in the embodiment of FIG. 3, wherein the same or similar reference numerals refer to the same or similar elements, and the same technical content is omitted. The previous embodiments may serve as reference for the omitted descriptions and thus no repetition is incorporated herein.

The distinguishing feature of the embodiment of FIG. 4 relative to the embodiment of FIG. 3 is that the black matrix BM overlaps the first color resist 110, the second color resist 112 and the third color resist 114 in a different manner.

Referring to FIG. 4, FIG. 4 illustrates the black matrix BM, the plurality of first color resists 110, the plurality of second color resists 112, the plurality of third color resists 114, the plurality of fourth color resists 210, the plurality of fifth color resists 212 and the plurality of sixth color resists 214 in the display device, and other elements are omitted. In the embodiment, the boundaries between the first color resist 110, the second color resist 112 and the third color resist 114 in each of the peripheral pixels X overlap the black matrix BM, and the black matrix BM respectively overlaps the first color resist 110, the second color resist 112 and the third color resist 114 in the single peripheral pixel X. For example, the two comb-shaped black matrixes BM overlap the first color resist 110, the second color resist 112 and the third color resist 114 in the first peripheral pixel X1 and the second peripheral pixel X2. In the single first peripheral pixel X1 or the single second peripheral pixel X2, the overlapping area of the black matrix BM and the first color resist 110 is A, the overlapping area of the black matrix BM and the second color resist 112 is B, the overlapping area of the black matrix BM and the third color resist 114 is C, wherein A:B:C is about 1:1:1. In the single first peripheral pixel X1, the areas of the first color resist 110, the second color resist 112 and the third color resist 114 blocked by the black matrix BM are the same, and the light passing through the single first peripheral pixel X1 may be blended into white light. In the single second peripheral pixel X2, the areas of the first color resist 110, the second color resist 112 and the third color resist 114 blocked by the black matrix BM are the same, and the light passing through the single second peripheral pixel X2 may be blended into white light. In the embodiment, the area of the second peripheral pixel X2 blocked by the black matrix is smaller than the area of the first peripheral pixel X1 blocked by the black matrix BM. In this manner, the transmittance of the first peripheral pixel X1 farther from the non-peripheral pixel Y is lower than the transmittance of the second peripheral pixel X2, such that the color non-uniformity sensed by human's eyes may be reduced.

According to the above, in the display device of the disclosure, with the black matrix BM which at least overlaps at least one of the first color resist 110, the second color resist 112 and the third color resist 114, the problem of color non-uniformity of the display device may be solved, thereby improving the display quality of the display device.

In summary, the display device of the disclosure includes the black matrix overlapping the color resist, with the black matrix BM which at least overlaps at least one of the first color resist, the second color resist and the third color resist, the problem of color non-uniformity of the display device may be solved, thereby improving the display quality of the display device.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising:
at least one peripheral pixel, the at least one peripheral pixel comprising:
a first color resist;
a second color resist, adjacent to the first color resist; and
a third color resist, adjacent to the second color resist;
at least one non-peripheral pixel, adjacent to the at least one peripheral pixel, the at least one non-peripheral pixel comprising a fourth color resist; and
a black matrix, at least overlapping at least one of the first color resist, the second color resist and the third color resist.

2. The display device according to claim 1, wherein the black matrix respectively overlaps the first color resist, the second color resist and the third color resist, an overlapping area of the black matrix and the first color resist is A, an overlapping area of the black matrix and the second color resist is B, an overlapping area of the black matrix and the third color resist is C, wherein A:B:C is about 1:1:1.

3. The display device according to claim 1, wherein the at least one peripheral pixel comprises a first peripheral pixel and a second peripheral pixel adjacent to each other, the first color resist and the third color resist of the first peripheral pixel overlap the black matrix, and the second color resist of the second peripheral pixel overlaps the black matrix.

4. The display device according to claim 1, wherein the first color resist, the second color resist and the third color resist are different colors, and the first color resist, the second color resist and the third color resist are respectively selected from a red color resist, a green color resist and a blue color resist.

5. The display device according to claim 1, wherein the fourth color resist is a red color resist, a green color resist or a blue color resist.

6. The display device according to claim 1, wherein an area of the at least one peripheral pixel and an area of the at least one non-peripheral pixel are approximately the same.

7. The display device according to claim 1, wherein an edge of the peripheral pixel and an edge of the non-peripheral pixel overlap the black matrix.

8. The display device according to claim 1, wherein areas of the first color resist, the second color resist and the third color resist are substantially the same.

9. The display device according to claim 1, wherein an area of the fourth color resist is substantially equal to an area of the first color resist, an area of the second color resist or an area of the third color resist.

10. The display device according to claim 1, the at least one non-peripheral pixel further comprising a fifth color resist and a sixth color resist, the display device further comprising:
three peripheral pixel electrodes, respectively overlapping the first color resist, the second color resist and the third color resist; and
three non-peripheral pixel electrodes, respectively overlapping the fourth color resist, the fifth color resist and the sixth color resist.

11. The display device according to claim 1, wherein the at least one peripheral pixel comprises a first peripheral pixel and a second peripheral pixel adjacent to each other, an overlapping area of the first peripheral pixel and the black matrix is M, and an overlapping area of the second peripheral pixel and the black matrix is N, wherein the second peripheral pixel is disposed between the first peripheral pixel and the at least one non-peripheral pixel, and M>N.
